(19) United States
(12) Patent Application Publication
(10) Pub. No.: US 2026/0059993 A1
(43) Pub. Date: Feb. 26, 2026

(54) DISPLAY DEVICE

(71) Applicant: LG Display Co., Ltd., Seoul (KR)

(72) Inventors: Junha HWANG, Siheung-si (KR); Jungwoo LEE, Seoul (KR)

(73) Assignee: LG Display Co., Ltd., Seoul (KR)

(21) Appl. No.: 19/287,180

(22) Filed: Jul. 31, 2025

(30) Foreign Application Priority Data
Aug. 22, 2024 (KR) 10-2024-0112801

(51) Int. Cl. H10K 59/80

(52) U.S. Cl. CPC H10K 59/8794; H10K 59/8793

(57) ABSTRACT

Disclosed is a display device including a display panel including a display area, a back plate disposed under the display panel, a heat-dissipative plate disposed to be spaced apart from the back plate, and a reflectance-reducing stack structure disposed between the back plate and the heat-dissipative plate.

### CROSS-REFERENCE TO RELATED APPLICATION

This application claims priority from Korean Patent Application No. 10-2024-0112801 filed on Aug. 22, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

A display device is applied to various electronic devices such as a TV, a mobile phone, a laptop, and a tablet. To this end, research is being conducted to develop a thinner, lighter, and less-power consuming display device.

Examples of the display device include a liquid crystal display device (LCD), a plasma display panel device (PDP), a field emission display device (FED), an electro-wetting display device (EWD), and an organic light emitting display (OLED).

Among the display devices that display various information as an image, the organic light emitting display device (OLED) includes a plurality of pixel areas arranged in a display area in which the image is displayed, and organic light-emissive elements arranged to correspond to the plurality of pixel areas. Because the organic light-emissive element is a self-light-emissive element that emits light by itself, the organic light emitting display device has advantages in that its response speed is higher, its light emission efficiency, luminance, and viewing angle are greater, and its contrast ratio and color reproduction are better than those of the liquid crystal display device.

### BRIEF SUMMARY

An embodiment of the present disclosure is intended to provide a display device that is disposed inside a vehicle in a form including a curved surface, provides various information and images, and has improved durability.

An embodiment of the present disclosure is intended to provide a display device that may reduce a reflectance of a heat-dissipative plate that discharges heat generated from a display panel to the outside.

An embodiment of the present disclosure is intended to improve reliability of a vehicle display device that is exposed to a high temperature or a high temperature and high humidity environment for a long time.

Accordingly, it is intended to build an eco-friendly product by delaying a replacement time of a vehicle display device by improving the vehicle display device to have an increased lifespan.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure includes: a display panel including a display area; a back plate disposed under the display panel; a heat-dissipative plate disposed to be spaced apart from the back plate; and a reflectance-reducing stack structure disposed between the back plate and the heat-dissipative plate.

According to the embodiment of the present disclosure, by disposing the reflectance-reducing stack structure between the back plate and the heat-dissipative plate of the display device, the high interface adhesion may be realized while reducing the reflectance of the heat-dissipative plate, thereby improving the reliability of the product.

According to the embodiment of the present disclosure, by disposing the reflectance-reducing stack structure between the back plate and the heat-dissipative plate of the display device, the reliability of the vehicle display device, which is exposed to the high temperature or high temperature and humidity environment for a long time, may be improved, thereby improving the lifespan of the device.

According to the embodiment of the present disclosure, by constructing the reflectance-reducing stack structure to include the reflectance-reducing layer and the adhesion enhancing layer and preventing the reflectance-reducing layer from being in direct contact with the heat-dissipative plate, the interfacial adhesive force may be increased to prevent the occurrence of the peeling defect.

According to the embodiment of the present disclosure, by allowing the binders of the reflectance-reducing layer and the adhesion enhancing layer of the reflectance-reducing stack structure to have the same base adhesive material, the interfacial adhesive force may be increased to prevent the occurrence of the peeling defect.

Accordingly, by improving the vehicle display device to have the increased lifespan and delaying the replacement time of the vehicle display device, the eco-friendly product may be built.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a diagram illustrating an example of an electronic device having a display device according to an embodiment of the present disclosure.

FIG. 2 is a plan view of a display panel in a display device according to embodiments of the present disclosure.

FIG. 3 is a diagram illustrating an example of a cross-section corresponding to a portion of a display area in FIG. 1.

FIG. 4 is a cross-sectional view of a display device in FIG. 2 taken along a line I-I′.

FIGS. 5 to 7 are diagrams for illustrating defects caused by a reflectance-reducing layer in FIG. 4.

FIG. 8 is a cross-sectional view illustrating a display device according to another embodiment of the present disclosure.

FIGS. 9 and 10 are diagrams for illustrating interfacial peeling phenomena for respective types of binder of a reflectance-reducing stack structure.

FIG. 11 is a table showing results of evaluating peel strength and reliability of reflectance-reducing stack structures.

FIGS. 12 to 14 are diagrams illustrating thickness changes of a reflection rate reducing stack structure in a display device according to another embodiment of the present disclosure.

FIGS. 15 and 16 are views illustrating methods for manufacturing a reflectance-reducing stack structure in a display device according to another embodiment of the present disclosure.

FIG. 17 is a view illustrating a display device including a reflectance-reducing stack structure according to still another embodiment of the present disclosure.

### DETAILED DESCRIPTIONS

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure. The claims are not limited by the disclosure.

A shape, a size, a ratio, an angle, a number, etc., disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to,” or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc., should not be construed such that any aspect or design as described is superior to or advantageous over other aspects or designs. Further, the term ‘or’ means ‘inclusive or’ rather than ‘exclusive or.’ That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, a display device according to each embodiment of the present disclosure will be described with reference to the attached drawings.

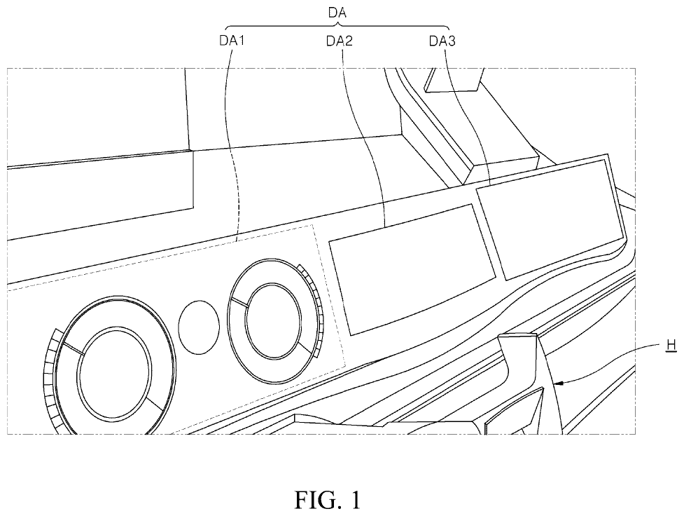

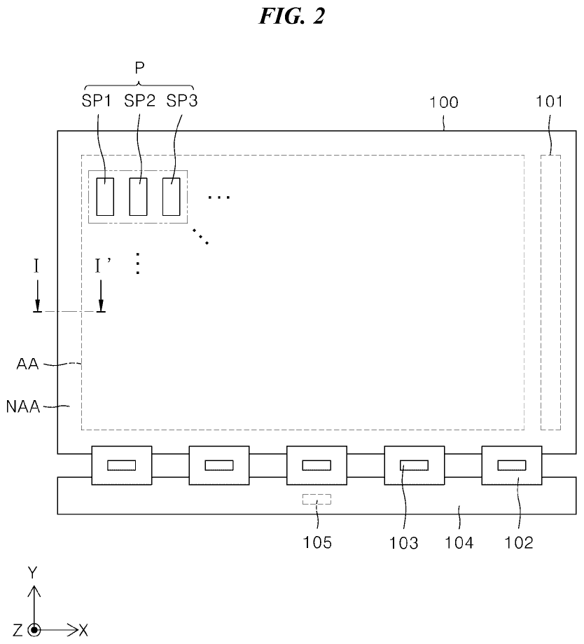

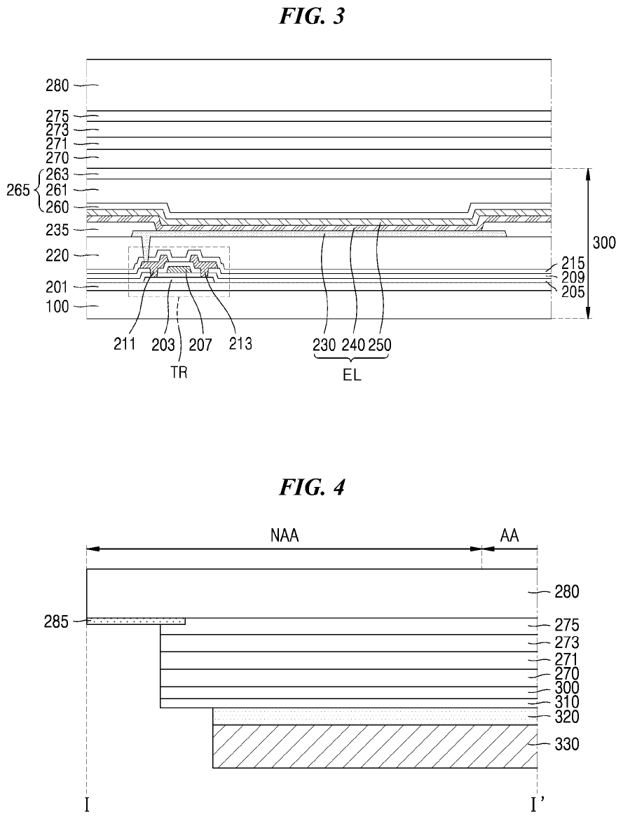

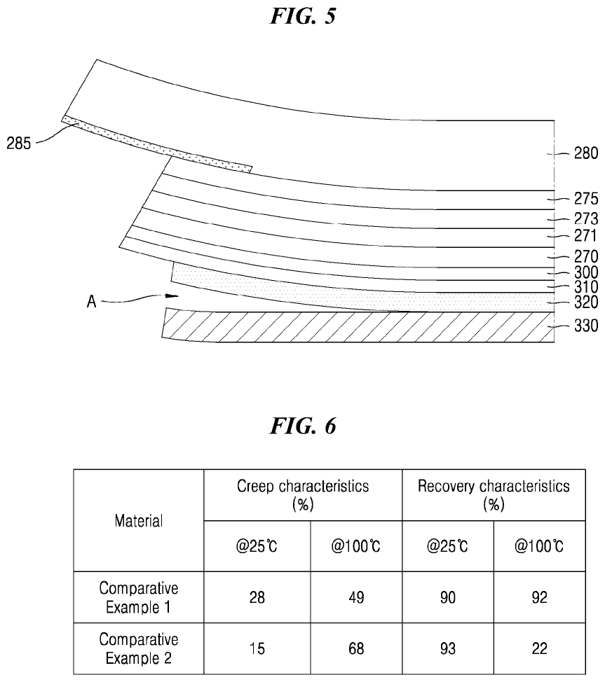

FIG. 1 is a diagram illustrating an example of an electronic device having a display device according to an embodiment of the present disclosure. FIG. 2 is a plan view of a display panel in a display device according to embodiments of the present disclosure. FIG. 3 is a diagram illustrating an example of a cross-section corresponding to a portion of a display area in FIG. 1. FIG. 4 is a cross-sectional view of a display device in FIG. 2 taken along a line I-I′. Although a display panel 300 in FIG. 2 is illustrated in a quadrangular shape for convenience of description, the display panel 300 may have a curved shape.

Referring to FIGS. 1 and 2, a display device DA according to an embodiment of the present disclosure may be an automotive display disposed on a front surface of a dashboard inside a vehicle. As a shape change of a display panel is facilitated, an applicable range is widening. Accordingly, the display device DA may be mounted on the dashboard disposed at the rear of a handle H inside the vehicle. For example, the vehicle display device DA may include a digital instrument panel DA1, a vehicle information guide display center information display (CID) DA2, and a passenger seat display DA3 that show various travel information.

The vehicle display device DA may provide a display surface having a shape corresponding to a shape of the front surface of the dashboard to prevent aesthetics of interior of the vehicle from deteriorating. For example, the vehicle display device DA may be implemented in a form including curved surfaces curved so as to be easily disposed on the front surface of the dashboard in a shape including curved surfaces curved in various directions.

The vehicle display device DA in the form including the curved surfaces includes the curved display panel 300. Because an application range of bending stress is different for each curved surface shape, influence of the bending stress on the display panel 300 may increase as various curved surface shapes are included.

Referring to FIG. 2, the display panel 300 may include a first substrate 100 including a display area AA and a non-display area NAA located outward of the display area AA. The first substrate 100 may be made of an insulating material. For example, the first substrate 100 may be made of glass or resin. In addition, the first substrate 100 may be made of a plastic material having flexibility, such as polyimide.

The display area AA may be an area in which an image is displayed. The non-display area NAA may be an area in which no image is displayed. The non-display area NAA may be located in a peripheral area (or an edge area) of the first substrate 100, but the present disclosure may not be limited thereto. For example, an area other than a light-emissive area in which light is emitted to the outside on the display area AA may be referred to as the non-display area NAA.

A plurality of pixels P may be disposed in the display area AA. The image may be displayed in the display area AA via the plurality of pixels P. Various lines, circuits, and the like for operating the plurality of pixels P of the display area AA may be disposed in the non-display area NAA. For example, driving circuits including a gate driving circuit and a data driving circuit may be disposed in the non-display area NAA. Several drivers 101 for driving the display area AA may be disposed in the non-display area NAA. For example, the drivers 101 may include a gate driver, a data driver, a touch controller, and the like, but the present disclosure may not be limited thereto.

A flexible printed circuit board 102 and a printed circuit board 104 may be disposed at an edge of at least one edge of the non-display area NAA. One side of the flexible printed circuit board 102 may be attached to the first substrate 100, and the other side thereof may be attached to the printed circuit board 104. The flexible printed circuit board 102 may include a film having flexibility. A driving integrated circuit chip 103 may be disposed on the flexible printed circuit board 102. The driving integrated circuit chip 103 may include a gate driver and a data driver.

The printed circuit board 104 may be electrically connected to one or more flexible printed circuit boards 102 and may supply signals to the driving integrated circuit chip 103. A component 105 for supplying the various signals to the driving integrated circuit chip 103 may be disposed on the printed circuit board 104. For example, the component 105 may include a timing controller, a power supply, a memory, a processor, or the like.

Each of the plurality of pixels P of the display area AA may be composed of a plurality of sub-pixels SP1, SP2, and SP3. The plurality of sub-pixels SP1, SP2, and SP3 may be arranged in an array on the display area AA. For example, the plurality of sub-pixels SP1, SP2, and SP3 may be spaced apart from each other in a first direction X and in a second direction Y intersecting the first direction X of the display area AA to form a matrix arrangement. The first direction may be an X-axis direction or a horizontal direction, and the second direction may be a Y-axis direction or a vertical direction. However, the present disclosure may not be limited thereto, and an arrangement order and an arrangement direction of the sub-pixels SP1, SP2, and SP3 may be variously changed.

A light-emissive element may be disposed in each of the plurality of sub-pixels SP1, SP2, and SP3. Each of the plurality of sub-pixels SP1, SP2, and SP3 may be connected to at least one transistor disposed on a substrate 401. Hereinafter, this will be described with reference to FIG. 3.

Referring to FIG. 3, a transistor TR may be disposed on the first substrate 100 of the display panel 300. On the first substrate 100, a driving circuit including various signal lines, transistors, capacitors, and the like may be disposed for each of the sub-pixels SP1, SP2, and SP3. The signal lines may include a gate line, a data line, a power line, and a reference line, and the transistors TR may include a switching transistor and a driving transistor.

The switching transistor is switched in response to a gate signal supplied to the gate line and supplies a data voltage supplied from the data line to the driving transistor, and selects the sub-pixels SP1, SP2, and SP3. The driving transistor serves to drive the light-emissive element by supplying power to the selected sub-pixel SP1, SP2, and SP3 selected from the switching transistor.

The capacitor serves to maintain the data voltage supplied to the driving transistor for one frame. Electrodes of the capacitor may be electrically connected to the driving transistor.

The transistor TR may include a semiconductor layer 203, a gate electrode 207, and source/drain electrodes 213 and 211. The gate insulating layer 205 may be disposed between the semiconductor layer 203 and the gate electrode 207. A buffer insulating layer 201 that reduces or prevents penetration of moisture or impurities may be further included between the substrate 100 and the semiconductor layer 203.

The semiconductor layer 203 may be made of an oxide semiconductor or silicon-based semiconductor material. For example, the semiconductor layer 203 may include a transparent oxide semiconductor material such as Indium-gallium-zinc-oxide (IGZO) or Indium-zinc-oxide (IZO). In another example, the semiconductor layer 203 may include a polysilicon semiconductor material.

The semiconductor layer 203 may include a channel area, a source area, and a drain area. The gate insulating layer 205 may be composed of a single layer or a plurality of layers of silicon oxide (SiOx) or silicon nitride (Sinx).

The gate electrode 207 may be disposed on the gate insulating layer 205. An area of the semiconductor layer 203 overlapping the gate electrode 207 in a vertical direction may be the channel area. The source area and the drain area may be located on both sides of the channel area.

A first insulating layer 209 may be disposed on the gate electrode 207. Source/drain electrodes 213 and 211 extending through the first insulating layer 209 and the gate insulating layer 205 may be disposed with the gate electrode 207 interposed therebetween. The source/drain electrodes 213 and 211 may include a source electrode 213 and a drain electrode 211. The source electrode 213 and the drain electrode 211 may be connected to the source area and the drain area of the semiconductor layer 203, respectively.

A second insulating layer 215 may be disposed on the source/drain electrodes 213 and 211. The second insulating layer 215 may be a passivation layer that protects the source/drain electrodes 213 and 211. The second insulating layer 215 may include an inorganic insulating film. For example, the second insulating layer 215 may be composed of a single layer or a plurality of layers of silicon oxide (SiOx) or silicon nitride (Sinx).

A protective layer 220 may be disposed on the second insulating layer 215. The protective layer 220 serves to planarize a step generated by a lower circuit element including the transistor TR. The protective layer 220 may include an organic insulating film. The protective layer 220 may have a multi-layer structure. The protective layer 220 may also be referred to as a planarization layer.

The protective layer 220 may include a contact via that exposes a portion of surfaces of the source/drain electrodes 213 and 211 of the transistor TR. The contact via may extend through the protective layer 220.

A first electrode 230 may be disposed on the protective layer 220. The first electrode 230 may include a transparent conductive oxide (TCO) such as indium tin oxide (ITO) or indium zinc oxide (IZO). Alternatively, the first electrode 230 may have a single-layer or multi-layer structure including a reflective metal film made of silver (Ag), aluminum (Al), gold (Au), nickel (Ni), chromium (Cr), and a compound thereof. However, embodiments of the present disclosure are not limited to such materials. The first electrode 230 may also be referred to as an anode electrode or a pixel electrode. In an example, a portion of the first electrode 230 may constitute the contact via and be electrically connected to the transistor TR.

A bank 235 may be disposed on the protective layer 220 and the first electrode 230. The bank 235 may be disposed to surround an edge of the first electrode 230. The bank 235 may distinguish neighboring sub-pixels from each other and define a light-emissive area.

A light-emissive layer 240 may be disposed on the first electrode 230. In an example, the light-emissive layer 240 may include an organic material that emits white light, but the present disclosure may not be limited thereto.

The light-emissive layer 240 may include a stack structure including a hole transport layer (HTL), an emission material layer (EML) and an electron transport layer (ETL), a hole blocking layer (HBL), a hole injecting layer (HIL), an electron blocking layer (EBL), and an electron injecting layer (EIL). In an example, the light-emissive layer 240 may have a multi-layer stack structure in which at least two layers are stacked, but the present disclosure may not be limited thereto.

The light-emissive layer 240 may be disposed on an entire surface of the first substrate 100. Accordingly, the light-emissive layer 240 may have a shape extending with continuity based on shapes of side surfaces and a top surface of the bank 235.

A second electrode 250 may be disposed on the light-emissive layer 240. The second electrode 250 may be a common layer commonly formed on the plurality of sub-pixels. The second electrode 250 may also be referred to as a cathode electrode or a common electrode. The second electrode 250 may include a material having a transmissive or semi-transmissive property. When the second electrode 250 has the transmissive property, it may include a transparent conductive oxide. For example, it may include indium tin oxide (ITO), indium zinc oxide (IZO), or the like. When the second electrode 250 has the semi-transmissive property, it may include a metal material such as magnesium (Mg), silver (Ag), or an alloy of magnesium (Mg) and silver (Ag).

A light-emissive element EL may be implemented including the first electrode 230, the light-emissive layer 240, and the second electrode 250. The display device according to an embodiment of the present disclosure may include an organic light-emissive element.

A scaling structure 265 may be disposed on the second electrode 250. The sealing structure 265 may prevent moisture or oxygen from penetrating into the transistor TR and the light-emissive element EL located thereunder. The sealing structure 265 may be a multi-layer structure of an inorganic insulating layer and an organic insulating layer. The sealing structure 265 may include at least one inorganic insulating layer or at least one organic insulating layer. For example, the scaling structure 265 may include a first encapsulating layer 260, a second encapsulating layer 261, and a third encapsulating layer 263.

Each of the first encapsulating layer 260 and the third encapsulating layer 263 may include an inorganic insulating material. For example, the inorganic insulating material may be selected from silicon nitride, aluminum nitride, zirconium nitride, titanium nitride, hafnium nitride, tantalum nitride, silicon oxide, aluminum oxide, titanium oxide, and the like. The second encapsulating layer 261 may planarize a step caused by the light-emissive element EL and the bank 235, and may prevent foreign substances from penetrating into the light-emissive element EL. The second encapsulating layer 261 may include an organic insulating material. For example, the organic insulating material may be a polyimide, photo resist, or photo acryl-based material, but the present disclosure may not be limited thereto.

A polarizing layer 270 may be disposed on top of the display panel 300, and may be disposed on the sealing structure 265. The polarizing layer 270 may suppress reflection of external light and change a polarization state of light emitted from the light-emissive element EL. The polarizing layer 270 may be bonded to the display panel 300 via an adhesive.

A light control film 273 may be disposed on top of the polarizing layer 270. The light control film 273 may be bonded to the polarizing layer 270 via a first adhesive layer 271. The first adhesive layer 271 may include an optically clearly adhesive film (OCA).

The light control film 273 may be a film to adjust directionality of light. The light control film 273 may control the directionality of light such that a screen provided from the display panel 300 is not reflected on a windshield of the vehicle.

A second substrate 280 may be disposed on top of the light control film 273. The second substrate 280 may cover the display panel 300 including the first substrate 100 to protect the transistor TR, the light-emissive element EL, and the circuit elements on the first substrate 100. The second substrate 280 transmits light emitted from the display panel 300 to allow the image to be viewed from the outside. The second substrate 280 may be referred to as a cover window, a window cover, or a cover glass.

The second substrate 280 may include a glass substrate. A second adhesive layer 275 may be further included between the second substrate 280 and the light control film 273. The second adhesive layer 275 may include an optically clear adhesive film (OCA).

In an example, the display panel 300 may further include a touch panel capable of inputting information via a touch operation. For example, the touch panel may be disposed between the second substrate 280 and the sealing structure 265.

A front surface of the display panel 300 may be a light exit surface through which light emitted from the light-emissive element EL is emitted to the outside through the second substrate 280. The user may view a video or an image emitted from the front surface of the display panel 300 and displayed via a front surface of the second substrate 280 in the display area AA.

A rear surface opposite to the front surface of the display panel 300 may be a light incident surface on which light emitted from the light-emissive element EL is incident. A light blocking pattern 285 may be disposed on the rear surface of the second substrate 280 on the non-display area NAA. The light blocking pattern 285 may prevent circuit patterns disposed on the non-display area NAA from being visually recognized by the user. For example, the circuit patterns disposed on the non-display area NAA may include metal lines, a pad electrode, an integrated circuit chip, a flexible circuit board, or a printed circuit board.

Referring to FIG. 4, for example, the light blocking pattern 285 may have a closed loop shape surrounding four edges of the rear surface of the second substrate 280. For example, the light blocking pattern 285 may be disposed to include an upper edge area, a lower edge area, a left edge area, and a right edge area. The light blocking pattern 285 may include a film mixed with an opaque pigment. For example, the opaque pigment may include carbon black or titanium black, but the present disclosure may not be limited thereto.

A back plate 310 may be disposed on a rear surface of the display panel 300. Referring to FIG. 4, the back plate 310 may be disposed under the display panel 300. The back plate 310 serves to reinforce rigidity of the display panel 300. For example, the back plate 310 may include a polymer film such as polyethylene terephthalate (PET) or polyimide. The back plate 310 may have a thickness of 50 μm to 200 μm to reinforce the first substrate 100 of the display panel 300.

A heat-dissipative plate 330 may be disposed under the back plate 310 and disposed to be spaced apart from the back plate 310. The heat-dissipative plate 330 may reinforce the rigidity of the display panel 300. The heat-dissipative plate 330 may dissipate heat generated inside the display panel 300 when the light-emissive element is operated to the outside. The heat-dissipative plate 330 may include a material having high thermal conductivity. In addition, the heat-dissipative plate 330 may include a metal material to serve as a ground member of the circuit elements disposed on the display panel 300. For example, the heat-dissipative plate 330 may include aluminum (Al), copper (Cu), or stainless steel (SUS), but the present disclosure may not be limited thereto. A thickness of the heat-dissipative plate 330 may be 18 μm to 700 μm.

On the heat-dissipative plate 330 according to an embodiment of the present disclosure, a reflectance-reducing layer 320 may be disposed between the back plate 310 and the heat-dissipative plate 330. The reflectance-reducing layer 320 may be at least in contact with one surface of the back plate. The reflectance-reducing layer 320 may have at least the same area size as that of the heat-dissipative plate 330.

The reflectance-reducing layer 320 may include a material having an adhesive property. In addition, the reflectance-reducing layer 320 may include a function of preventing or reducing reflection of external light by the heat-dissipative plate 330 including a metal material. For example, the reflectance-reducing layer 320 may be an opaque adhesive member. For example, the reflectance-reducing layer 320 may include a pressure sensitive adhesive (PSA) made of an opaque material. The reflectance-reducing layer 320 may be made of a material including opaque pigment particles in a base adhesive material. For example, the pressure sensitive adhesive made of the opaque material may include a base adhesive material and opaque pigment particles dispersed in the base adhesive material. For example, the base adhesive material may include a base resin, acryl, rubber, or silicone material. The opaque pigment particles may include a material having an optical density value greater than 0.9 in a visible light range to block external light. For example, the opaque pigment particles may be made of carbon black, nickel black, or copper chromite black.

In an example, a method for using a heat-dissipative plate coated with black ink on a surface and attaching the heat-dissipative plate coated with the black ink onto the back plate 310 via a transparent adhesive member may be considered. However, it may be difficult to uniformly coat the black ink on the heat-dissipative plate, and defects may occur during a coating process and lower a yield.

Accordingly, in an embodiment of the present disclosure, the heat-dissipative plate 330 may be attached to the back plate 310 via the reflectance-reducing layer 320 instead of the heat-dissipative plate coated with the black ink on the surface.

The reflectance-reducing layer 320 may be uniformly disposed between the heat-dissipative plate 330 and the back plate 310 and may reduce the external light reflectance of the heat-dissipative plate 330, as it is the material with the opaque pigment included in the base adhesive material.

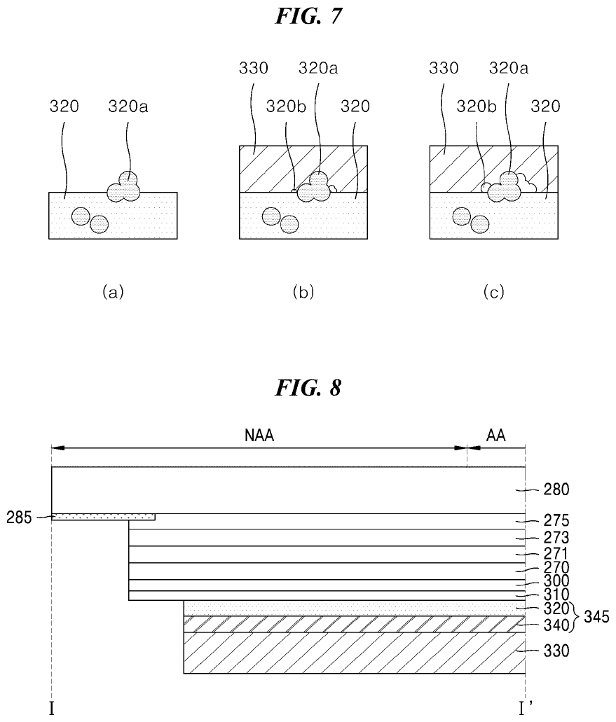

FIGS. 5 to 7 are diagrams for illustrating defects caused by a reflectance-reducing layer in FIG. 4. FIG. 5 illustrates a lifting phenomenon of a display device. FIG. 6 is a table showing creep characteristics and recovery characteristics of a reflectance-reducing layer. FIG. 7 illustrates a cause of irregular stain.

Because the vehicle display device DA (see FIG. 1) is exposed to the outside for most of the time, criteria for evaluation conditions of thermal resistance of not causing a physical change at a high temperature and moisture resistance are higher than those of a general display device. In addition, as the vehicle display device DA is implemented as the curved display panel 300, the heat-dissipative plate 330 attached to the display panel 300 is also curved along the shape of the curved display panel 300. Accordingly, for the heat-dissipative plate 330 to maintain a force of fixing with the curved display panel 300, high adhesiveness for the reflectance-reducing layer 320 is required.

The reflectance-reducing layer 320 may be the material in which the opaque pigment particles are added to the base adhesive material. The opaque pigment particles may not improve crosslinking density of the base adhesive material, and as the opaque pigment particles are added to the base adhesive material, the crosslinking density and entanglement of the base adhesive material may be reduced. When the reflectance-reducing layer 320 is exposed to a high-temperature environment for a long time in this state, the base adhesive material may be deteriorated and the adhesiveness thereof may be lowered, so that a defect of being separated from the heat-dissipative plate 330 may occur.

Referring to FIG. 6, the creep characteristics and the recovery characteristics were measured using 180-degree peel strength measuring equipment. Each material of Comparative Example 1 and Comparative Example 2 was measured as a sample having a radius of 8 mm with a thickness of 1 mm.

Measurement conditions for the creep characteristics were a pressure of 10,000 Pa and 600 seconds, and measurement conditions for the recovery characteristics were a pressure of 0 Pa and 600 seconds. The creep characteristic is a strain rate of deformation from an original shape when the pressure is applied to each material of Comparative Example 1 and Comparative Example 2 under the above measurement conditions, and the recovery characteristic is a recovery rate that returns to the original shape when the pressure is removed.

Comparative Example 1 is a pressure sensitive adhesive made of a transparent material, and Comparative Example 2 is a pressure sensitive adhesive made of an opaque material including a black pigment.

Referring to FIG. 6, it may be seen that in Comparative Example 1, the recovery characteristic was 90% or greater at a room temperature (25° C.) and a high temperature (95° C.), whereas in Comparative Example 2, the recovery rate was 90% or greater at the room temperature (25° C.) but was 22% at the high temperature (95° C.). Accordingly, it may be seen that the pressure sensitive adhesive made of the opaque material including the black pigment has a lower recovery rate at the high temperature than the pressure sensitive adhesive made of the transparent material. This may be understood that the pressure sensitive adhesive made of the opaque material including the black pigment deteriorates cohesion of black particles that become unstable at the high temperature and thus resilience thereof decreases.

In addition, when the reflectance-reducing layer 320 is in direct contact with a surface of the heat-dissipative plate 330, a defect such as an irregular stain may occur on the heat-dissipative plate 330. For example, referring to FIG. 7, opaque pigment particles 320a added to the base adhesive material may protrude from a surface of the reflectance-reducing layer 320 to generate surface irregularities ((a) in FIG. 7). In the process of bonding the reflectance-reducing layer 320 having the surface irregularities to the heat-dissipative plate 330, fine bubbles 320b may be generated between the reflectance-reducing layer 320 and the heat-dissipative plate 330 (see (b) in FIG. 7). The fine bubbles 320b may be generated as the heat-dissipative plate 330 is relatively hard compared to a polymer film having a flexible property and thus does not cover the surface irregularities of the reflectance-reducing layer 320. In addition, when the fine bubbles 320b are generated and are exposed to a high-temperature environment, the fine bubbles 320b may expand at the high temperature, and the irregular stain in which the expanded fine bubbles 320b are visually recognized may occur ((c) in FIG. 7).

Accordingly, a component capable of maintaining the fixing force with the heat-dissipative plate while reducing the external light reflectance of the heat-dissipative plate may be included.

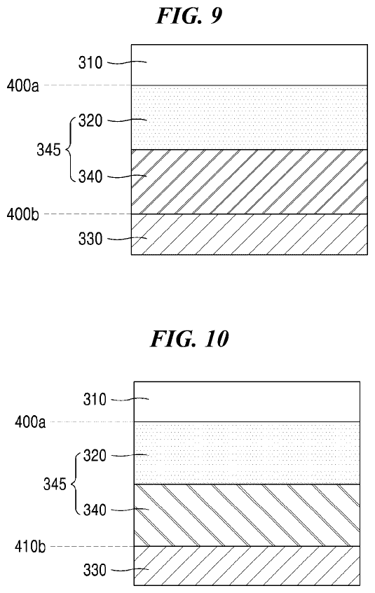

FIG. 8 is a cross-sectional view illustrating a display device according to another embodiment of the present disclosure. In FIG. 8, the same reference numerals will be assigned to the same components as the components described in FIGS. 3 and 4, and a description thereof will be briefly made or omitted.

Referring to FIG. 8, the back plate 310 may be disposed on a bottom surface of the display panel 300. The polarizing layer 270, the light control film 273, and the second substrate 280 may be disposed on a top surface of the display panel 300. The polarizing layer 270 and the light control film 273 may be bonded to each other via the first adhesive layer 271, and the second substrate 280 may be bonded to the lower structure via the second adhesive layer 275. In an example, the display panel 300 may further include the touch panel capable of inputting information via the touch operation. For example, the touch panel may be disposed between the second substrate 280 and the sealing structure 265.

The heat-dissipative plate 330 may be disposed to be spaced apart from the back plate 310. The heat-dissipative plate 330 may reinforce the rigidity of the display panel 300 and may dissipate heat generated inside the display panel 300 to the outside. To this end, the heat-dissipative plate 330 may include the metal material having high thermal conductivity, but the present disclosure may not be limited thereto. For example, the heat-dissipative plate 330 may include aluminum (Al), copper (Cu), or stainless steel (SUS). The thickness of the heat-dissipative plate 330 may be 18 μm to 700 μm. When the thickness of the heat-dissipative plate 330 is smaller than 18 μm, a pinhole may be generated, resulting in a defect. In addition, when the thickness of the heat-dissipative plate 330 is greater than 700 μm, a repulsive force is generated because of the thickness of the heat-dissipative plate 330 and thus it is difficult to implement the curved display panel.

A reflectance-reducing stack structure 345 may be disposed between the back plate 310 and the heat-dissipative plate 330.

The reflectance-reducing stack structure 345 may include the reflectance-reducing layer 320 and an adhesion enhancing layer 340. The reflectance-reducing layer 320 may be disposed beneath the back plate 310 with one surface in contact with one surface of the back plate 310, and one surface of the adhesion enhancing layer 340 may be disposed on top of the heat-dissipative plate 330 and be in contact with one surface of the heat-dissipative plate 330. In addition, the other surface of the reflectance-reducing layer 320 and the other surface of the adhesion enhancing layer 340 may be disposed to be in contact with each other.

The reflectance-reducing layer 320 may prevent or reduce the external light reflection by the heat-dissipative plate 330. The reflectance-reducing layer 320 may include the pressure sensitive adhesive (PSA) made of the opaque material. The reflectance-reducing layer 320 may be made of the material including the opaque pigment particles in the base adhesive material.

One surface of the adhesion enhancing layer 340 may be in contact with one surface of the heat-dissipative plate 330. The adhesion enhancing layer 340 may increase an adhesive force between the heat-dissipative plate 330 and the reflectance-reducing stack structure 345 to prevent the heat-dissipative plate 330 from being peeled off. For example, the adhesion enhancing layer 340 may prevent the reflectance-reducing layer 320 from being in direct contact with the heat-dissipative plate 330 and generating the irregular stain on the surface of the heat-dissipative plate 330 or prevent the defect in which the reflectance-reducing layer 320 is lifted.

The adhesion enhancing layer 340 may include a pressure sensitive adhesive (PSA) made of a transparent material. For example, a base adhesive material of the adhesion enhancing layer 340 may include a base resin, acryl, rubber, or silicon material.

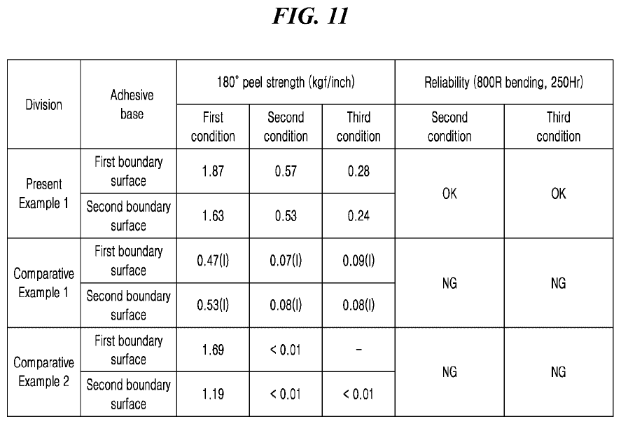

To increase the adhesive force, the reflectance-reducing layer 320 and the adhesion enhancing layer 340 have a cross-linking structure with each other, wherein a base adhesive material of a binder of the reflectance-reducing layer 320 constituting the cross-linking structure is identical with a base adhesive material of a binder of the adhesion enhancing layer 340 constituting the cross-linking structure. This will be described later in FIGS. 9 and 10.

In the display device according to another embodiment of the present disclosure, the reflectance-reducing stack structure 345 may be disposed between the back plate 310 and the heat-dissipative plate 330, thereby reducing the reflectance of the heat-dissipative plate 330 and improving reliability of the vehicle display device exposed to a high temperature or a high temperature and high humidity environment.

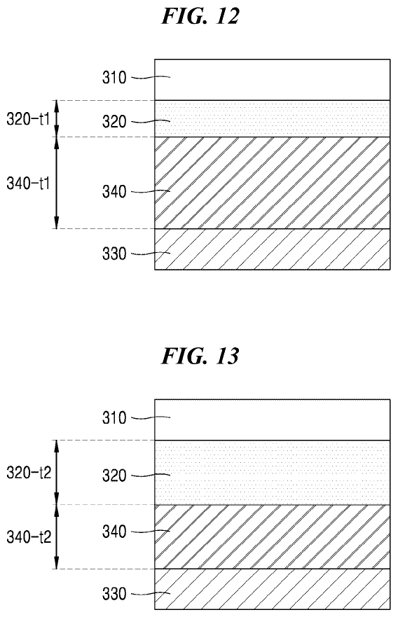

FIGS. 9 and 10 are diagrams for illustrating interfacial peeling phenomena for respective types of binder of a reflectance-reducing stack structure. FIG. 11 is a table showing results of evaluating peel strength and reliability of reflectance-reducing stack structures. In FIGS. 9 and 10, only the back plate 310, the reflectance-reducing layer 320, the adhesion enhancing layer 340, and the heat-dissipative plate 330 are illustrated for convenience of description. In FIG. 11, a letter ‘I’ represents a result of peeling at an interface.

Referring to FIG. 9, one surface of the back plate 310 may be disposed to be in contact with the reflectance-reducing layer 320 of the reflectance-reducing stack structure 345, and one surface of the heat-dissipative plate 330 may be disposed to be in contact with the adhesion enhancing layer 340 of the reflectance-reducing stack structure 345.

The base adhesive material of a binder of the reflectance-reducing layer 320 constituting the cross-linking structure is identical with the base adhesive material of a binder of the adhesion enhancing layer 340 constituting the cross-linking structure. For example, the base adhesive material may include a base resin, acryl, rubber, or silicon material. In this regard, when the base adhesive material of the reflectance-reducing layer 320 is the acryl material, the base adhesive material of the adhesion enhancing layer 340 may be the same acryl material.

Accordingly, at each of a first interface 400a at which the reflectance-reducing layer 320 and the back plate 310 are in contact with each other and a second interface 400b at which the adhesion enhancing layer 340 and the heat-dissipative plate 330 are in contact with each other, the layer and the plate may be attached to each other via the base adhesive material including the same binder.

Referring to FIG. 10, the base adhesive materials of the reflectance-reducing layer 320 and the adhesion enhancing layer 340 may have binders participating in the structure of cross-linking to each other made of different materials. For example, when the base adhesive material of the reflectance-reducing layer 320 is the acryl material, the base adhesive material of the adhesion enhancing layer 340 may be the silicon material having a binder different from that of the reflectance-reducing layer 320.

Accordingly, at each of the first interface 400a at which the reflectance-reducing layer 320 and the back plate 310 are in contact with each other and the second interface 410b at which the adhesion enhancing layer 340 and the heat-dissipative plate 330 are in contact with each other, the layer and the plate may be attached to each other via the base adhesive material including the different binder.

In FIG. 11, the peel strength and the reliability of the reflectance-reducing stack structures were evaluated. Measurement of the adhesive force was made at a speed of 5 mm/s using a 180-degree peel strength meter. Each of the reflectance-reducing layer 320 and the adhesion enhancing layer 340 was disposed in a width of 1 inch. A 180-degree peel strength measurement was performed at the first interface between the back plate and the reflectance-reducing layer and at the second interface between the adhesion enhancing layer and the heat-dissipative plate, respectively. In addition, the reflectance-reducing stack structure was disposed between the back plate and the heat-dissipative plate, and the measurement was performed after a day or after autoclave. The 180-degree peel strength was measured under a first condition, a second condition, and a third condition. The first condition was a temperature of 25 degrees to measure a room temperature adhesion, and the second condition was a high temperature (100° C.) to measure a high temperature adhesion. Further, the third condition was a temperature of 85° C. and a humidity of 85RH % to measure a high temperature and high humidity adhesion.

Referring to FIG. 11, Present Example 1 is a case in which the base adhesive materials of the reflectance-reducing layer 320 and the adhesion enhancing layer 340 of the reflectance-reducing stack structure 345 have the same binder according to an embodiment of the present disclosure. Comparative Example 1 is a case in which the reflectance-reducing layer 320 and the adhesion enhancing layer 340 of the reflectance-reducing stack structure 345 have different binders. In addition, Comparative Example 2 is a case in which only a single layer of the reflectance-reducing layer 320 is formed.

It may be seen that in Present Example 1, the reflectance-reducing layer 320 and the adhesion enhancing layer 340 show an adhesive property equal to or greater than 0.5 kgf/inch at the high temperature and equal to or greater than 0.2 kgf/inch at the high temperature and high humidity with the back plate 310 and the heat-dissipative plate 330, respectively. In addition, it may be seen that they were not peeled even in the reliability test maintained for 250 hours under a condition of bending to 800 R. Here, the 800 R represents a degree of bending of a circle with radius 800 mm.

In contrast, it may be seen that in Comparative Example 1, peeling (I) occurred at the room temperature, high temperature, and high temperature and high humidity conditions. In addition, it may be seen that a defect occurred in the reliability test. In addition, in Comparative Example 2, it may be seen that the adhesive property was lower than 0.01 kg/inch under the high temperature condition, and a defect occurred in the reliability test. Accordingly, it may be seen that in Comparative Example 2, peeling occurred even when a force smaller than 10 g is applied.

Accordingly, when the reflectance-reducing stack structure 345 including the reflectance-reducing layer 320 and the adhesion enhancing layer 340 that include the same binder materials is disposed between the back plate 310 and the heat-dissipative plate 330, high interface adhesion may be realized while reducing the reflectance of the heat-dissipative plate 330, thereby improving reliability of a product.

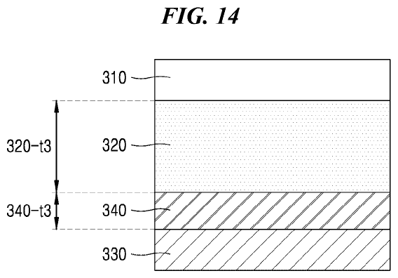

FIGS. 12 to 14 are diagrams illustrating thickness changes of a reflection rate reducing stack structure in a display device according to another embodiment of the present disclosure.

Referring to FIGS. 12 to 14, in a display device according to another embodiment of the present disclosure, optical properties and adhesive properties may be different depending on a ratio of components in a total thickness of the reflectance-reducing stack structure.

Referring to FIGS. 12 to 14, each of the reflectance-reducing stack structures may include the adhesion enhancing layer 340 and the reflectance-reducing layer 320. One surface of the adhesion enhancing layer 340 may be attached to the heat-dissipative plate 330, and one surface of the reflectance-reducing layer 320 may be attached to the back plate 310. The total thickness of the reflectance-reducing stack structure may be in a range of 25 μm to 200 μm, e.g., 50 μm. In the total thickness of the reflectance-reducing stack structure, the reflectance-reducing layer 320 may have a first thickness at least greater than 10 μm, and the adhesion enhancing layer 340 may have a second thickness at least greater than 10 μm.

Referring to FIG. 12, the adhesion enhancing layer 340 may have a first thickness 340-t1, and the reflectance-reducing layer 320 may have a second thickness 320-t1 that is smaller than the first thickness 340-t1. For example, in the total thickness of the reflectance-reducing stack structure, the first thickness 340-t1 may be 40 μm and the second thickness 320-t1 may be 10 μm.

Referring to FIG. 13, the adhesion enhancing layer 340 may have a first thickness 340-t2, and the reflectance-reducing layer 320 may have a second thickness 320-t2 equal to the first thickness 340-t2. For example, in the total thickness of the reflectance-reducing stack structure, each of the first thickness 340-t2 and the second thickness 320-t2 may be 25 μm.

Referring to FIG. 14, the adhesion enhancing layer 340 may have a first thickness 340-t3, and the reflectance-reducing layer 320 may have a second thickness 320-t3 greater than the first thickness 340-t3. For example, in the total thickness of the reflectance-reducing stack structure, the first thickness 340-t1 may be 10 μm, and the second thickness 320-t1 may be 40 μm.

As the thickness of the adhesion enhancing layer 340 increases, the adhesion to the heat-dissipative plate 330 may be strengthened. As the thickness of the reflectance-reducing layer 320 increases, the optical density (OD) value may increase, so that the reflectance of the heat-dissipative plate 330 may be reduced.

The reflectance of the heat-dissipative plate 330 may be reduced only when the optical density (OD) value is greater than 0.9. However, when the thickness of the reflectance-reducing layer 320 is smaller than 10 μm, the optical density (OD) value becomes smaller than 0.9. Accordingly, it is preferable that the thickness of the reflectance-reducing layer 320 is greater than 10 μm.

In addition, when the thickness of the adhesion enhancing layer 340 is smaller than 10 μm, the adhesion to the heat-dissipative plate 330 is rapidly reduced, and thus it is preferable that the thickness of the adhesion enhancing layer 340 is greater than 10 μm.

A peeling defect may occur depending on a method for manufacturing the components of the reflectance-reducing stack structure. Hereinafter, it will be described with reference to the drawings.

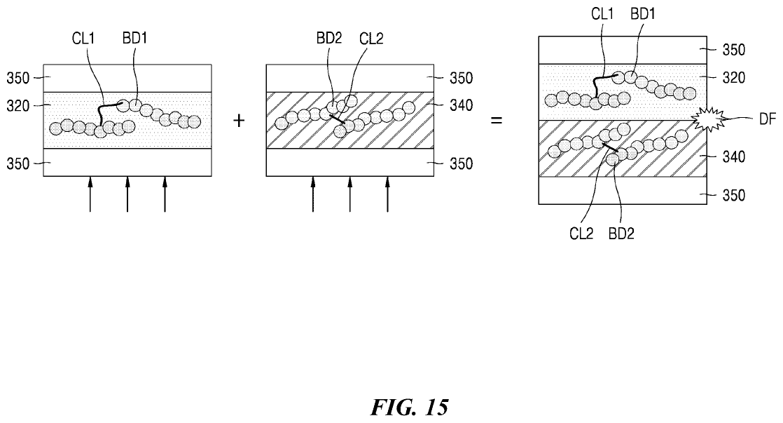

FIGS. 15 and 16 are views illustrating methods for manufacturing a reflectance-reducing stack structure in a display device according to another embodiment of the present disclosure.

As one of methods for bonding the reflectance-reducing layer 320 and the adhesion enhancing layer 340 to each other, there is a method of performing thermal curing and/or UV curing on each of the reflectance-reducing layer 320 and the adhesion enhancing layer 340 and then bonding them together.

For example, as shown in FIG. 15, the reflectance-reducing layer 320 that has undergone the thermal curing and/or the UV curing and the adhesion enhancing layer 340 that has undergone the thermal curing and/or the UV curing are prepared. Here, a release film 350 is attached to both surfaces of each of the reflectance-reducing layer 320 and the adhesion enhancing layer 340.

The reflectance-reducing layer 320 and the adhesion enhancing layer 340 are in a state of being cross-linked by crosslinkers CL1 and CL2 in binders BD1 and BD2, respectively, as they have undergone the curing process. The binders BD1 and BD2 may also be referred to as base adhesive materials.

Subsequently, the release film 350 on one surface of each of the reflectance-reducing layer 320 and the adhesion enhancing layer 340 is removed. In addition, surfaces of the reflectance-reducing layer 320 and the adhesion enhancing layer 340 to which the release films 350 are not attached are positioned to face each other, and then bonded together in a roll-to-roll manner.

Then, because interior of the reflectance-reducing layer 320 and the adhesion enhancing layer 340 are already in a chemically bonded state by the cross-linkers CL1 and CL2, the chemical bonding no longer occurs at the interface where the reflectance-reducing layer 320 and the adhesion enhancing layer 340 are in contact with each other.

Accordingly, the adhesion between the reflectance-reducing layer 320 and the adhesion enhancing layer 340 may be reduced, and thus a separation defect DF may easily occur by an external environment (e.g., a high temperature and high humidity environment).

Therefore, in an embodiment of the present disclosure, a process method capable of preventing separation from occurring at the interface between the reflectance-reducing layer 320 and the adhesion enhancing layer 340 of the reflectance-reducing stack structure may be used.

For example, referring to FIG. 16, a reinforcing structure may be formed by performing the bonding in the roll to roll manner and then performing the thermal curing and/or the UV curing. To this end, first, the reflectance-reducing layer 320 and the adhesion enhancing layer 340 are prepared. The release film 350 is attached to one surface of each of the reflectance-reducing layer 320 and the adhesion enhancing layer 340. It is preferable that the reflectance-reducing layer 320 and the adhesion enhancing layer 340 include the binders BD of the same material.

Next, surfaces of the reflectance-reducing layer 320 and the adhesion enhancing layer 340 to which the release films 350 are not attached are positioned to face each other, and then bonded together in the roll-to-roll manner. Further, the curing is performed in the thermal and/or UV manner.

Then, at the interface where the reflectance-reducing layer 320 and the adhesion enhancing layer 340 including the binders BD of the same material are in contact with each other, a chemical bonding may occur between the binders BD with the cross-linkers, thereby improving interface adhesion.

In one example, a structure that improves the adhesion between the back plate 310 and the reflectance-reducing layer 430 may be included.

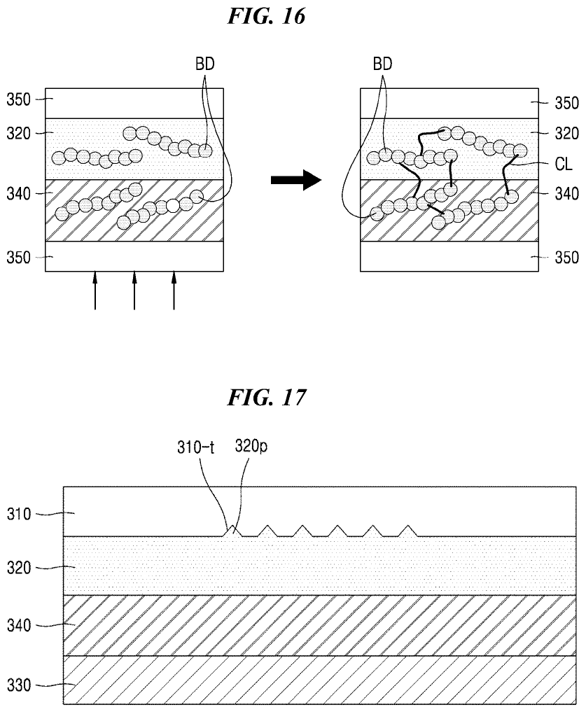

FIG. 17 is a view illustrating a display device including a reflectance-reducing stack structure according to still another embodiment of the present disclosure. In FIG. 17, for convenience of description, only the back plate 310, the reflectance-reducing layer 320, the adhesion enhancing layer 340, and the heat-dissipative plate 330 are illustrated.

Referring to FIG. 17, a plurality of pattern structures 310-t may be disposed in one surface of the back plate 310. The plurality of pattern structures 310-t may be in a shape of being recessed in a thickness direction of the back plate 310. Neighboring pattern structures 310-t may be arranged to be spaced apart from each other. The plurality of pattern structures 310-t may have a shape extending in a longitudinal direction of the back plate 310, but the present disclosure may not be limited thereto.

In addition, FIG. 17 illustrates that a cross-section has a triangular shape for convenience of description, but the present disclosure is not limited thereto. For example, the cross-section may include a trapezoidal and quadrangular shape.

The reflectance-reducing layer 320 may be disposed to be in contact with the surface in which the plurality of pattern structures 310-t are disposed of the back plate 310. The reflectance-reducing layer 320 may fill the plurality of pattern structures 310-t having the recessed shape. Accordingly, the reflectance-reducing layer 320 may include a first area in which a surface in contact with a flat surface of the back plate 310 is disposed, and a second area in which a plurality of protruding patterns 320p protruding beyond the flat surface are disposed while filling the plurality of pattern structures 310-t. Because a surface area of the interface between the reflectance-reducing layer 320 and the back plate 310 is increased by the plurality of pattern structures 310-t, the adhesion may be improved by 10% or greater.

In addition, an area in the back plate 310 in which the plurality of pattern structures 310-t are disposed may have a first thickness, and an area in which the plurality of pattern structures 310-t are not disposed may have a second thickness. The first thickness is smaller than the second thickness. In the area having the first thickness, interface stress generated by the shape in which the display panel is bent or curved may be reduced. Accordingly, a defect caused by the interface stress may be prevented from occurring in the display device, thereby maintaining the reliability of the product.

The display device according to various aspects and embodiments of the present disclosure may be described as follows.

One aspect of the present disclosure provides a display device comprising: a display panel including a display area; a back plate disposed under the display panel; a heat-dissipative plate disposed to be spaced apart from the back plate; and a reflectance-reducing stack structure disposed between the back plate and the heat-dissipative plate.

In some embodiment of the display device, the reflectance-reducing stack structure includes a reflectance-reducing layer at least in contact with one surface of the back plate.

In some embodiment of the display device, the reflectance-reducing stack structure further includes an adhesion enhancing layer disposed under the reflectance-reducing layer, wherein one surface of the reflectance-reducing layer is in contact with the one surface of the back plate, wherein one surface of the adhesion enhancing layer is in contact with one surface of the heat-dissipative plate.

In some embodiment of the display device, the display device further comprise: a first substrate on which a transistor and a light-emissive element configured to output light for displaying an image in the display area are disposed; a polarizing layer disposed on top of the display panel; a light control film disposed on top of the polarizing layer; and a second substrate disposed on top of the light control film.

In some embodiment of the display device, the reflectance-reducing layer includes a pressure sensitive adhesive made of an opaque material.

In some embodiment of the display device, the pressure sensitive adhesive made of the opaque material includes a base adhesive material and opaque pigment particles dispersed in the base adhesive material.

In some embodiment of the display device, the opaque pigment particles are made of carbon black, nickel black, or copper chromite black.

In some embodiment of the display device, the reflectance-reducing layer and the adhesion enhancing layer have a cross-linking structure with each other, wherein a base adhesive material of a binder of the reflectance-reducing layer constituting the cross-linking structure is identical with a base adhesive material of a binder of the adhesion enhancing layer constituting the cross-linking structure.

In some embodiment of the display device, a total thickness of the reflectance-reducing stack structure is in a range of 25 μm to 200 μm.

In some embodiment of the display device, in the total thickness of the reflectance-reducing stack structure, the reflectance-reducing layer has a first thickness at least greater than 10 μm.

In some embodiment of the display device, in the total thickness of the reflectance-reducing stack structure, the adhesion enhancing layer has a second thickness at least greater than 10 μm.

In some embodiment of the display device, the back plate further includes a plurality of pattern structures recessed in a thickness direction in the one surface thereof.

In some embodiment of the display device, the reflectance-reducing layer includes: a first area in contact with a flat surface of the back plate; and a second area including a plurality of protruding patterns protruding beyond the flat surface while filling the plurality of pattern structures.

In some embodiment of the display device, the back plate has a first thickness in a first area where the plurality of pattern structures are disposed, and has a second thickness in a second area where the plurality of pattern structures are not disposed, wherein the first thickness is smaller than the second thickness.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including a display area;
a back plate disposed under the display panel;
a heat-dissipative plate spaced apart from the back plate; and
a reflectance-reducing stack structure disposed between the back plate and the heat-dissipative plate.

2. The display device of claim 1, wherein the reflectance-reducing stack structure includes a reflectance-reducing layer in contact with a surface of the back plate.

3. The display device of claim 2, wherein the reflectance-reducing stack structure further includes an adhesion enhancing layer disposed under the reflectance-reducing layer,
wherein a surface of the reflectance-reducing layer is in contact with the surface of the back plate, and
wherein a surface of the adhesion enhancing layer is in contact with a surface of the heat-dissipative plate.

4. The display device of claim 1, further comprising:
a first substrate;
a transistor disposed on the first substrate;
a light-emissive element disposed on the first substrate, the light-emissive element configured to output light for displaying an image in the display area;
a polarizing layer disposed on top of the display panel;
a light control film disposed on top of the polarizing layer; and
a second substrate disposed on top of the light control film.

5. The display device of claim 2, wherein the reflectance-reducing layer includes a pressure sensitive adhesive made of an opaque material.

6. The display device of claim 5, wherein the pressure sensitive adhesive made of the opaque material includes a base adhesive material and opaque pigment particles dispersed in the base adhesive material.

7. The display device of claim 6, wherein the opaque pigment particles are made of carbon black, nickel black, or copper chromite black.

8. The display device of claim 3, wherein the reflectance-reducing layer and the adhesion enhancing layer have a cross-linking structure with each other, wherein a base adhesive material of a binder of the reflectance-reducing layer constituting the cross-linking structure is identical with a base adhesive material of a binder of the adhesion enhancing layer constituting the cross-linking structure.

9. The display device of claim 3, wherein a total thickness of the reflectance-reducing stack structure is in a range of 25 μm to 200 μm.

10. The display device of claim 9, wherein the reflectance-reducing layer has a thickness greater than 10 μm.

11. The display device of claim 9, wherein the adhesion enhancing layer has a thickness greater than 10 μm.

12. The display device of claim 3, wherein the back plate further includes a plurality of pattern structures recessed in a thickness direction of the surface of the back plate.

13. The display device of claim 12, wherein the reflectance-reducing layer includes:
a first area in contact with a flat surface of the back plate; and
a second area including a plurality of protruding patterns protruding beyond the flat surface while filling the plurality of pattern structures.

14. The display device of claim 12, wherein the back plate has a first thickness in a first area of the back plate where the plurality of pattern structures are disposed, and the back plate has a second thickness in a second area of the back plate where the plurality of pattern structures are not disposed,
wherein the first thickness is less than the second thickness.
